(19) United States
(12) Patent Application Publication
(10) Pub. No.: US 2023/0207230 A1
(43) Pub. Date: Jun. 29, 2023

(54) HIGH-FREQUENCY SIGNAL SWITCHING APPARATUS, AND TESTING APPARATUS HAVING THE SAME

(71) Applicant: BIZLINK (KUNSHAN) CO., LTD., Kunshan (CN)

(72) Inventor: Jin'an XIE, Kunshan (CN)

(21) Appl. No.: 18/088,799

(22) Filed: Dec. 27, 2022

(30) Foreign Application Priority Data
Dec. 29, 2021 (CN) 202111638669.X

(51) Int. Cl. H01H 9/00

(52) U.S. Cl. CPC H01H 9/00

(57) ABSTRACT

A high-frequency signal switching apparatus and a testing apparatus are provided. The switching apparatus comprises at least one switching module comprising a first input port; a second input port; a plurality of output ports; a primary-stage switching element group comprising at least a first primary-stage switch and a second primary-stage switch, and a final-stage switching element group comprising a plurality of final-stage switches; wherein a head-end interface of the first primary-stage switch is electrically connected to the first input port, a head-end interface of the second primary-stage switch is electrically connected to the second input port; and each final-stage switch is optionally electrically connected to the first primary-stage switch, the second primary-stage switch, and two of the plurality of output ports simultaneously, thereby the two output ports being respectively and optionally electrically connected to the first input port and the second input port.

### TECHNICAL FIELD

The present disclosure relates to the field of electronic test devices, and in particular, to a high-frequency signal switching apparatus, and a testing apparatus.

### BACKGROUND

In a signal integrity (SI) test on an electronic device a conventional test environment is to use a switching apparatus as an intermediate connector between the electronic device under test and a testing apparatus.

An existing method is to connect a four-to-one switch (1P4T switch/also named as SP4T) respectively to different input ports (e.g. a first input port and a second input port). Any of four ports of the four-to-one switch connected to the first input port may be controlled to be connected to the first input port through software, and any of four ports of the four-to-one switch connected to the second input port may be controlled to be connected to the second input port through software. In this way, each output port cannot be optionally connected to different input ports to form a pathway.

In order to realize that the output ports can be optionally connected to different input ports without replacement of wiring, especially when a large amount of output ports are required, either a switch with more branch ports, such as a 1P8T switch, or a switch with more stages is selected. For example, when 16 electronic devices under test are required to be connected simultaneously, 10 four-to-one switches may coordinate with 16 two-to-one switches, which are classified into three stages, wherein two 1P4T switches are used as the first stage, which are in one-to-one correspondence to the different input ports; eight 1P4T switches are used as the second stage, and the eight 1P4T switches are classified into two groups (four 1P4T switches in each group), head-end interfaces of one group of 1P4T switches are connected to four tail-end interfaces of one 1P4T switch in the first stage, and head-end interfaces of the other group of 1P4T switches are connected to four tail-end interfaces of the other 1P4T switch in the first stage; sixteen 1P2T/1P4T switches are used as the third stage, having tail-end interfaces respectively in one-to-one correspondence to output ports (devices under test) and two head-end interfaces thereof respectively connected to one of the tail-end interfaces of the 1P4T switches in the first group in the second stage and one of the tail-end interfaces of the 1P4T switches in the second group in the second stage.

When more than 16 electronic devices under test are required to be connected simultaneously, the switching apparatus requires more stages of switches. However, in the case of a larger number of stages, firstly, an increase in a number of the switches leads to a high cost; secondly, as stacking of errors in more than 3 stages of switches, it is difficult to control test accuracy well; thirdly, defect rates and signal quality consistency of various components are poor; in addition, a number of coaxial cables required to connect switches in adjacent stages increases, and the wiring is complicated, which easily causes wiring errors and affects accuracy of test results. Details may be obtained with reference to the schematic diagram on page 4 of the specification (“R&S [symbol] ZN-Z84 Switch Matrix Specifications”) of the R&S [symbol] ZN-Z84high-frequency signal switching apparatus (Switch Matrix) launched by ROHDE & SCHWARZ Company, from which an example of a four-stage switch system with 12 input ports can be seen.

### SUMMARY

The present disclosure relates to a high-frequency signal switching apparatus with a reduced number of stacked stages of switches and a testing apparatus, so as to improve switching precision.

The present disclosure adopts the following technical solutions:

A high-frequency signal switching apparatus, comprising at least one switching module, the switching module comprising:

a first input port;

a second input port;

a plurality of output ports;

a primary-stage switching element group comprising a plurality of primary-stage switches, wherein the plurality of primary-stage switches comprises at least a first primary-stage switch and a second primary-stage switch, a head-end interface of the first primary stage switch is electrically connected to the first input port, and a head-end interface of the second primary-stage switch is electrically connected to the second input port; and

a final-stage switching element group comprising a plurality of final-stage switches, wherein the plurality of final-stage switches comprises at least one first final-stage switch, and the first final-stage switch is optionally electrically connected to the first primary-stage switch, the second primary-stage switch, and two of the plurality of output ports simultaneously, so that the two output ports are respectively and optionally electrically connected to the first input port or the second input port.

Further, no switch is provided between the first primary-stage switch and the first input port, and no switch is provided between the second primary-stage switch and the second input port; and a number of the plurality of final-stage switches is less than a number of the output ports.

Further, each of the final-stage switches is a 2P2T switch, each 2P2T switch comprises two head-end interfaces and two tail-end interfaces, and the two head-end interfaces of each of the final-stage switches are optionally electrically connected to one of the tail-end interfaces of the first primary-stage switch and one of the tail-end interfaces of the second primary-stage switch respectively; and

each of the final-stage switches is optionally electrically connected to the plurality of output ports respectively.

Further, the final-stage switches are further provided with a disconnected state, and during the disconnected state, neither of the head-end interfaces thereof is electrically connected to neither of the tail-end interfaces thereof

Further, each of the switching modules comprises 8 to 16 output ports, and each of the final-stage switches is configured to be able to select, under software control, one of the two head-end interfaces electrically connected to one of the two tail-end interfaces.

Further, both the first primary-stage switch and the second primary-stage switch comprise a head-end interface and a plurality of tail-end interfaces, wherein the first primary-stage switch is configured with more tail-end interfaces than the finial-stage switches comprised in the switching module or with as many tail-end interfaces as the final-stage switches comprised in the switching module;

the first primary-stage switch is configured that the head-end interface thereof may optionally be electrically connected to one of the tail-end interfaces thereof under software control; and

the second primary-stage switch is configured that the head-end interface thereof may optionally be electrically connected to one of the tail-end interfaces thereof under software control.

Further, the first primary-stage switch is further configured with a disconnected state, and during the disconnected state, the head-end interface thereof is electrically disconnected from each of the tail-end interfaces thereof; and

the second primary-stage switch is further configured with a disconnected state, and during the disconnected state, the head-end interface thereof is electrically disconnected from each of the tail-end interfaces thereof.

Further, a number of the output ports is equal to twice a number of the final-stage switches; and the switching module adopts a two-stage hierarchical structure, comprising at least two 1P8T switches and at least eight 2P2T switches.

Optionally, only one switching module is provided;

the primary-stage switches are two 1P8T switches, the final-stage switches are eight 2P2T switches; or the primary-stage switches are two 1P4T switches, the final-stage switches are four 2P2T switches.

Optionally, N switching modules are provided; the switching apparatus further comprises two 1PNT switches, wherein the first input ports of N switching modules are connected to tail-end interfaces of one 1PNT switch, and the second input ports of N switching modules are connected to tail-end interfaces of the other 1PNT switch.

In another aspect, the present disclosure provides a testing apparatus, comprising the high-frequency signal switching apparatus as described above, wherein the output port of the high-frequency signal switching apparatus is configured for connection with a device under test, and the first input port and the second input port of the high-frequency signal switching apparatus are configured to be connected to different detector connection ports.

In yet another aspect, the present disclosure provides a test system, comprising a first detector connection port, a second detector connection port, and the testing apparatus as described above, wherein the first detector connection port is configured to be electrically connected to the first input port, and the second detector connection port is configured to be electrically connected to the second input port.

In addition, the present disclosure further provides a high-frequency signal switching apparatus, comprising at least one switching module, wherein the switching module comprises a first input port, a second input port, a primary-stage switching element group, and a final-stage switching element group;

wherein,

the primary-stage switching element group comprises a plurality of primary-stage switches, the plurality of primary-stage switches comprise a first primary-stage switch and a second primary-stage switch, wherein a head-end interface of the first primary-stage switch is electrically connected to the first input port, no switch is provided between the first primary-stage switch and the first input port, a head-end interface of the second primary-stage switch is electrically connected to the second input port, and no switch is provided between the second primary-stage switch and the second input port; and

the final-stage switching element group comprises a plurality of final-stage switches, each of the final-stage switches is optionally electrically connected to the plurality of primary-stage switches and a plurality of output ports simultaneously, thereby each of the output ports being optionally electrically connected to the first input port or the second input port through the final-stage switching element group and the primary-stage switching element group arranged in a multi-stage hierarchical structure.

The technical solutions according to the present disclosure bring the following beneficial effects:

a. switching connections between at most 16 output ports and input port PA/PB can be satisfied with only a two-stage switches are stacked into fewer stages, and switching precision is higher;

b. 16 output ports can be provided with only 10 switches, the structure is simple, and costs are low;

c. switches in adjacent stages can be connected only through 16 coaxial cables, and wiring errors are less likely.

### BRIEF DESCRIPTION OF DRAWINGS

In order to more clearly illustrate the embodiments of the present application, the accompanying drawings required to be used in the description of the embodiments will be briefly introduced below. Apparently, the accompanying drawings in the following description show merely some embodiments of the present application, and those of ordinary skill in the art may still derive other drawings from these accompanying drawings without creative efforts.

FIG. 1 is a schematic structural diagram of a high-frequency signal switching apparatus according to an embodiment of the present disclosure;

FIG. 2 is a schematic diagram of an internal structure of a 1P8T switch;

FIG. 3 is a schematic diagram of an internal structure of a 2P2T switch: and

FIG. 4 is a schematic structural diagram of the high-frequency signal switching apparatus according to another embodiment of the present disclosure.

### DETAILED DESCRIPTION

In order to make those skilled in the art better understand the technical solutions of the present disclosure, the technical solutions in the embodiments of the present disclosure will be described clearly and completely below with reference to the accompanying drawings in the embodiments of the present disclosure. Apparently, the described embodiments are merely some of rather than all of the embodiments of the present disclosure. All other embodiments acquired by those of ordinary skill in the art without creative efforts based on the embodiments in the present disclosure shall fall within the protective scope of the present disclosure.

It is to be noted that the terms such as “first” and “second” used in the specification, claims, and the drawings of the present disclosure are intended to distinguish similar objects, but are not intended to describe a particular order or sequence. It is to be understood that data used in this manner may be interchangeable where appropriate, so that the embodiments of the present disclosure described herein can be realized in an order in addition to those illustrated or described herein. The wording “comprise/include/have parts A” or “comprise/include/have a part A” as referred to in the specification and claims of the present disclosure is defined as that at least one and two or more parts A are provided without conflicting with the initial disclosure. In addition, the terms “comprise”, “include”, “have”, and any other variants thereof mean to cover non-exclusive inclusion, for example, a process, method, apparatus, product, or device that comprises a list of steps or units is not necessarily limited to those expressly listed steps or units, but may comprise other steps or units not expressly listed or inherent to the process, method, product, or device.

Electronic device products, especially passive high-speed line products, generally need an SI test. In a process of receiving high-frequency signals, a waveform test, an eye diagram measurement, a jitter test and other means may be used. An embodiment of the present disclosure provides a high-frequency signal switching apparatus, for easily switching a port of a connector under test to a port of a testing apparatus, and for controllably switching an electronic device under test to a different input port so as to connect a different external detector connection port without plugging or unplugging the electronic device product (e.g., a cable under test). However, specific applications thereof are not used as a basis for limiting the protective scope of the present disclosure.

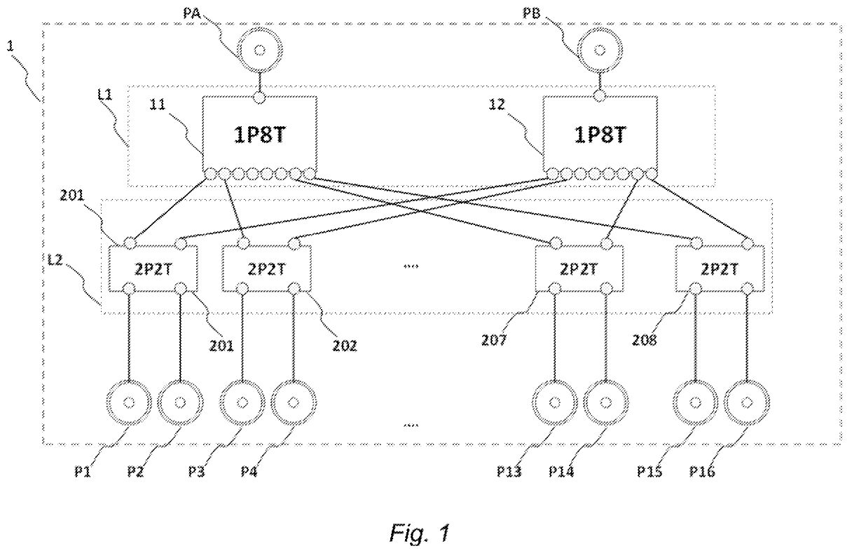

Referring to FIG. 1, in the present embodiment, a high-frequency signal switching apparatus D comprises a single switching module 1. The switching module 1 comprises a first input port PA, a second input port PB, a primary-stage switching element group L1, a final-stage switching element group L2, and a plurality of output ports P1 to P16, which are specifically described below one by one:

As shown in FIG. 1, the output ports are denoted by P1 to P16. In the present embodiment, at most 16 electronic devices under test can be simultaneously connected to the switching apparatus in the present embodiment. By stacking only two stages of switches (i.e., the primary-stage switching element group L1 and the final-stage switching element group L2), any one of the 16 electronic devices under test may switch at any time among states of connecting to the first input port PA, connecting to the second input port PB, and disconnection. Obviously, it may be understood that the number of the output ports may also be less than 16.

The primary-stage switching element group L1 is described below:

Referring to FIG. 1, the primary-stage switching element group L1 comprises at least a first primary-stage switch 11 and a second primary-stage switch 12. In FIG. 1, the first primary-stage switch 11 is configured with a head-end interface located on an upper side thereof (relative to an upstream path) and tail-end interfaces located on a lower side thereof (relative to a downstream path). In FIG. 1, the second primary-stage switch 12 is configured with a head-end interface located on an upper side thereof and tail-end interfaces located on a lower side thereof. The head-end interface of the first primary-stage switch 11 is electrically connected to the first input port PA, and the head-end interface of the second primary-stage switch 12 is electrically connected to the second input port PB. The number of the primary-stage switches in the primary-stage switching element group L1 is not limited to two in the present disclosure. In an embodiment, the primary-stage switching element group L1 may further comprise, for example, a third primary-stage switch, whose connection relationship may be the same as that of the first primary-stage switch 11, and the possibility of comprising a fourth primary-stage switch is not excluded.

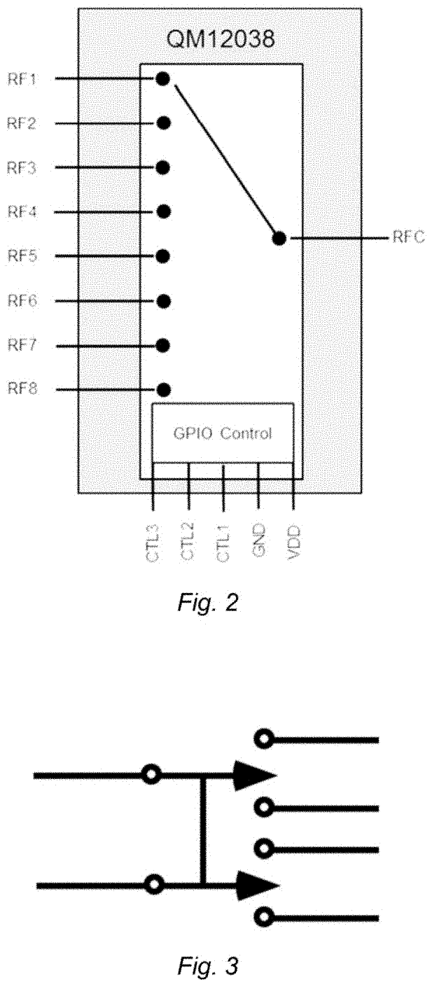

As shown in FIG. 1, both the first primary-stage switch 11 and the second primary-stage switch 12 are configured with 8 tail-end interfaces. That is, the first primary-stage switch 11 and the second primary-stage switch 12 are 1P8T switches. In an embodiment, an internal circuit structure of the 1P8T switch is shown in FIG. 2. The circuit structure optionally adopts a GPIO control module. The 1P8T switch in the present embodiment is provided with an initial state. In this state, an input terminal of the switch is disconnected frons any of the output ports. Under software control, the head-end interface of the first primary-stage switch 11 is optionally electrically connected to a target tail-end interface among its 8 tail-end interfaces. The head-end interface of the second primary-stage switch 12 is optionally electrically connected to a target tail-end interface among its 8 interfaces. The target interface may be described in further detail below in the description of an operation process of the switch.

The final-stage element group L2 is described below.

Referring to FIG. 1, the final-stage switching element group L2 comprises 8 final-stage switches (denoted by numbers 201 to 208). The final-stage switches are of a type of 2P2T switches (also named as DPDT switches). Each 2P2T switch comprises two head-end interfaces (relative to an upstream path) and two tail-end interfaces (relative to a downstream path). The output ports (P1 to P16) are electrically connected to 16 tail-end interfaces of the 8 final-stage switches in a one-to-one correspondence manner. Each final-stage switch is configured that one head-end interface thereof is connected to one of the tail-end interfaces of the first primary-stage switch 11 and the other head-end interface thereof is connected to one of the tail-end interfaces of the second primary-stage switch 12. Moreover, it is limited that one tail-end interface of the first primary-stage switch 11/the second primary-stage switch 12 can only be electrically connected to one head-end interface of one final-stage switch, but one tail-end interface of one 1P8T switch cannot be simultaneously connected to two head-end interfaces of one 2P2T switch. In the present embodiment, a plurality of tail-end interfaces of the 1P8T switch are not classified into master and slave ones. Therefore, on the premise that one tail-end interface of the primary-stage switching element group L1 is not simultaneously connected to two head-end interfaces of the final-stage switching element group L2, it is okay for one tail-end interface of the 1P8T switch to be specifically electrically connected to one of the head-end interfaces of either the final-stage switch 201 or the final-stage switch 208. After a corresponding connection relationship is determined, by setting a corresponding software control program, an output port can be controllably switched to being connected to a different input port to connect a different external detector connection port without changing the wiring. That is, any output ports of P1 to P16 may be optionally electrically connected to the first input port PA or the second input port PB sequentially through the final-stage switching element group L2 and the primary-stage switching element group L1 arranged in a two-stage hierarchical structure.

An internal circuit structure of the 2P2T switch is shown in FIG. 3. In the present embodiment, the 2P2T switch is provided with an initial state. In this state, two input ports of the switch are both disconnected from any of the output ports. Under software control, one target head-end interface in the two head-end interfaces of the 2P2T switch is electrically connected to one target tail-end interface in the two tail-end interfaces. The target head-end interface/target tail-end interface is described by taking FIG. 1 as an example.

For example, the first input port PA is connected to a first high-frequency detector connection port of a high-frequency detector (e.g., a network analyzer), the second input port PB is connected to a second high-frequency detector connection port of the high-frequency detector, and a high-frequency value (range) of the first high-frequency detector connection port may be different from that of the second high-frequency detector connection port. Some or all of the output ports P1 to P16 are in one-to-one correspondence to electronic devices under test (such as cables). Taking a test path of the electronic device connected to the output port P1 as an example, the output port P1 is optionally connected to the first high-frequency detector connection port or the second high-frequency detector connection port for performance testing. If the output port P1 is required to be connected to the first high-frequency detector connection port, referring to the directions in FIG. 1, a lower left tail-end interface and an upper left head-end interface of the final-stage switch 201 are respectively the target tail-end interface and the target head-end interface of the 2P2T switch, which are controlled to be electrically connected within the final-stage switch 201. At the same time, the first tail-end interface from the left of the first primary-stage switch 11 is used as the target tail-end interface of the 1P8T switch described above and is controlled to be electrically connected to the head-end interface of the 1P8T switch within the first primary-stage switch 11. In this way, the connection between the electronic device connected to the output port P1 and the first high-frequency detector connection port is completed. If the output port P1 is required to be connected to the second high-frequency detector connection port, referring to the directions in FIG. 1, the lower left tail-end interface (the target tail-end interface) and an upper right head-end interface (the target head-end interface) of the final-stage switch 201 are controlled to be electrically connected within the 2P2T switch. At the same time, the first tail-end interface from the left (the target tail-end interface) of the second primary-stage switch 12 is controlled to be electrically connected to the head-end interface of the 1P8T switch within the second primary-stage switch 12. In this way, the connection between the electronic device connected to the output port P1 and the second high-frequency detector connection port is completed.

In an embodiment, a test path of the electronic device connected to the output port P14 is taken as an example. The output port P14 is optionally connected to the first high-frequency detector connection port or the second high-frequency detector connection port for performance testing. If the output port P14 is required to be connected to the first high-frequency detector connection port, referring to the directions in FIG. 1, a lower right tail-end interface and an upper left head-end interface of the final-stage switch 207 are respectively the target interface and the target head-end interface of the 2P2T switch, which are controlled to be electrically connected within the final-stage switch 207. At the same time, the second tail-end interface from the right of the first primary-stage switch 11 is used as the target tail-end interface of the 1P8T switch described above and is controlled to be electrically connected to the head-end interface of the 1P8T switch within the first primary-stage switch 11. In this way, the connection between the electronic device connected to the output port P14 and the first high-frequency detector connection port is completed. If the output port P14 is required to be connected to the second high-frequency detector connection port, referring to the directions in FIG. 1, the lower right tail-end interface (the target tail-end interface) and an upper right head-end interface (the target head-end interface) of the final-stage switch 207 are controlled to be electrically connected within the 2P2T switch. At the same time, the second tail-end interface from the right (the target tail-end interface) of the second primary-stage switch 12 is controlled to be electrically connected to the head-end interface of the 1P8T switch within the second primary-stage switch 12. In this way, the connection between the electronic device connected to the output port P14 and the second high-frequency detector connection port is completed.

Obviously, the above embodiments are described only with an example in which at most 16 electronic devices are simultaneously connected. Apparently, the above high-frequency signal switching apparatus is also applicable for 1-15 electronic devices to switch connection to the input port PA or the input port PB, provided that excess interface(s) are idle.

In an embodiment of the present disclosure, when the number of electronic devices under test simultaneously connected is reduced to, for example, 12, two 1P6T switches may be selected for the primary-stage switching element group L1 as the first primary-stage switch and the second primary-stage switch, and six 2P2T switches may be selected for the final-stage switching element group L2. Specifically, the 1P6T switches of the primary-stage switching element group L1 and the six 2P2T switches of the final-stage switching element group L2 are wired in the same manner as the wiring of the 1P8T switches of the primary-stage switching element group L1 and the eight 2P2T switches of the final-stage switching element group L2 in the above embodiment. That is, the tail-end interfaces of the primary-stage switches are in one-to-one correspondence to the head-end interfaces of the final-stage switches. In addition, it is to be emphasized that the present disclosure is not limited to a two-stage structure. If required, additional switching elements can be inserted between the primary-stage switching element group L1 and the final-stage switching element group L2 for further expansion into a multi-stage structure such as a three-stage or four-stage structure.

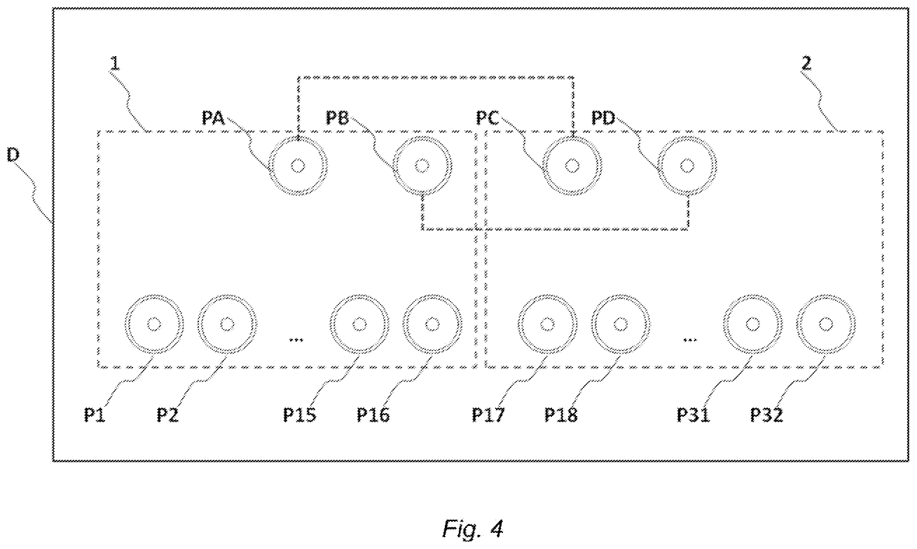

Besides, if required, the structure may be extended as FIG. 4 to further comprise one or more switching modules 2. The switching modules 2 comprise a third input port PC and a fourth input port PD. The third input port PC and the first input port PA are arranged on the same circuit board and may be electrically connected or isolated. The fourth input port PD and the second input port PB are arranged on the same circuit board and may be electrically connected or isolated. In an embodiment of the present disclosure, 2 switching modules are provided; the switching apparatus further comprises two 1P2T switches, wherein the input port PA and input port PC are connected to two tail-end interfaces of one 1P2T switch, and the input port PB and input port PD are connected to two tail-end interfaces of the other 1P2T switch. A total of up to 32 tail-end interfaces may be comprised.

It should be pointed that for those of ordinary skill in the art, some improvements and refinements, which shall also fall within the protective scope of the present application, may be made without departing from the principle of the present application.

Although the present invention has been disclosed in the form of embodiments and variations thereon, it will be understood that numerous additional modifications and variations could be made thereto without departing from the scope of the invention.

For the sake of clarity, it is to be understood that the use of ‘a’ or ‘an’ throughout this application does not exclude a plurality, and ‘comprising’ does not exclude other steps or elements.

What is claimed is:

1. A high-frequency signal switching apparatus, comprising at least one switching module, the switching module comprising:
a first input port;
a second input port;
a plurality of output ports;
a primary-stage switching element group comprising a plurality of primary-stage switches, wherein the plurality of primary-stage switches comprises at least a first primary-stage switch and a second primary-stage switch, a head-end interface of the first primary-stage switch is electrically connected to the first input port, and a head-end interface of the second primary-stage switch is electrically connected to the second input port; and
a final-stage switching element group comprising a plurality of final-stage switches, wherein the plurality of final-stage switches comprises at least one first final-stage switch, and the first final-stage switch is optionally electrically connected to the first primary-stage switch, the second primary-stage switch, and two of the plurality of output ports simultaneously, thereby the two output ports being respectively and optionally electrically connected to the first input port or the second input port.

2. The high-frequency signal switching apparatus according to claim 1, wherein no switch is provided between the first primary-stage switch and the first input port, and no switch is provided between the second primary-stage switch and the second input port.

3. The high-frequency signal switching apparatus according to claim 1, wherein a number of the plurality of final-stage switches is less than a number of the output ports.

4. The high-frequency signal switching apparatus according to claim 1, wherein each of the final-stage switches is a 2P2T switch, each 2P2T switch comprises two head-end interfaces and two tail-end interfaces, and the two head-end interfaces of each of the final-stage switches are optionally electrically connected to one of the tail-end interfaces of the first primary-stage switch and one of the tail-end interfaces of the second primary-stage switch respectively.

5. The high-frequency signal switching apparatus according to claim 4, wherein each of the final-stage switches is optionally electrically connected to the plurality of output ports respectively.

6. The high-frequency signal switching apparatus according to claim 3, wherein the final-stage switches are further provided with a disconnected state, and during the disconnected state, neither of the head-end interfaces thereof is electrically connected to neither of the tail-end interfaces thereof.

7. The high-frequency signal switching apparatus according to claim 4, wherein each of the switching modules comprises 8 to 16 output ports, and each of the final-stage switches is configured to be able to select, under software control, one of the two head-end interfaces electrically connected to one of the two tail-end interfaces.

8. The high-frequency signal switching apparatus according to claim 1, wherein both the first primary-stage switch and the second primary-stage switch comprise a head-end interface and a plurality of tail-end interfaces, wherein the first primary-stage switch is configured with more tail-end interfaces than the final-stage switches comprised in the switching module or with as many tail-end interfaces as the final-stage switches comprised in the switching module.

9. The high-frequency signal switching apparatus according to claim 8, wherein the first primary-stage switch is configured that the head-end interface thereof may optionally be electrically connected to one of the tail-end interfaces thereof under software control; and
the second primary-stage switch is configured that the head-end interface thereof may optionally be electrically connected to one of the tail-end interfaces thereof under software control.

10. The high-frequency signal switching apparatus according to claim 8, wherein the first primary-stage switch is further provided with a disconnected state, and during the disconnected state, the head-end interface thereof is electrically disconnected from each of the tail-end interfaces thereof; and
the second primary-stage switch is further provided with a disconnected state, and during the disconnected state, the head-end interface thereof is electrically disconnected from each of the tail-end interfaces thereof.

11. The high-frequency signal switching apparatus according to claim 1, wherein a number of the output polls is equal to twice a number of the final-stage switches; and the switching module adopts a two-stage hierarchical structure, comprising at least two 1P8T switches and at least eight 2P2T switches.

12. The high-frequency signal switching apparatus according to claim 1, wherein only one switching module is provided;
the primary-stage switches are two 1P8T switches, the final-stage switches are eight 2P2T switches; or the primary-stage switches are two 1P4T switches, the final-stage switches are four 2P2T switches.

13. The high-frequency signal switching apparatus according to claim 1, wherein N switching modules are provided;
the switching apparatus further comprises two 1PNT switches, wherein the first input ports of N switching modules are connected to tail-end interfaces of one 1PNT switch, and the second. input ports of N switching modules are connected to tail-end interfaces of the other 1PNT switch.

14. A testing apparatus, comprising the high-frequency signal switching apparatus according to claim 1, wherein the output port of the high-frequency signal switching apparatus is configured for connection with a device under test, and the first input port and the second input port of the high-frequency signal switching apparatus are configured to be connected to different detector connection ports.

15. A high-frequency signal switching apparatus, comprising at least one switching module, wherein the switching module comprises a first input port, a second input port, a primary-stage switching element group, and a final-stage switching element group;
wherein the primary-stage switching element group comprises a plurality of primary-stage switches, the plurality of primary-stage switches comprises a first primary-stage switch and a second primary-stage switch, wherein a head-end interface of the first primary-stage switch is electrically connected to the first input port, no switch is provided between the first primary-stage switch and the first input port, a head-end interface of the second primary-stage switch is electrically connected to the second input port, and no switch is provided between the second primary-stage switch and the second input port; and
the final-stage switching element group comprises a plurality of final-stage switches, each of the final-stage switches is optionally electrically connected to the plurality of primary-stage switches and a plurality of output ports simultaneously, thereby each of the output ports being optionally electrically connected to the first input port or the second input port through the final-stage switching element group and the primary-stage switching element group arranged in a multi-stage hierarchical structure.

16. The high-frequency signal switching apparatus according to claim 15, wherein a number of the output ports is equal to twice a number of the final-stage switches; and the switching module adopts a two-stage hierarchical structure, comprising at least two 1P8T switches and at least eight 2P2T switches.

17. The high-frequency signal switching apparatus according to claim 15, wherein each of the final-stage switches is a 2P2T switch, each 2P2T switch comprises two bead-end interfaces and two tail-end interfaces, and the two head-end interfaces of each of the final-stage switches are optionally electrically connected to one of the tail-end interfaces of the first primary-stage switch and one of the tail-end interfaces of the second primary-stage switch respectively.

18. The high-frequency signal switching apparatus according to claim 17, wherein each of the switching modules comprises 8 to 16 output ports, and each of the final-stage switches is configured to be able to select, under software control one of the two head-end interfaces electrically connected to one of the two tail-end interfaces.

19. The high-frequency signal switching apparatus according to claim 15, wherein both the first primary-stage switch and the second primary-stage switch comprise a head-end interface and a plurality of tail-end interfaces, wherein the first primary-stage switch is configured with more tail-end interfaces than the final-stage switches comprised in the switching module or with as many tail-end interfaces as the final-stage switches comprised in the switching module.

20. The high-frequency signal switching apparatus according to claim 19, wherein the first primary-stage switch is configured that the head-end interface thereof may optionally be electrically connected to one of the tail-end interfaces thereof under software control; and
the second primary-stage switch is configured that the head-end interface thereof may optionally be electrically connected to one of the fail-end interfaces thereof under software control.
